(19) United States
(12) Patent Application Publication
(10) Pub. No.: US 2024/0219441 A1
(43) Pub. Date: Jul. 4, 2024

(54) Probe Structure for Radio Frequency Testing, and Radio Frequency Test Apparatus and System

(71) Applicant: Honor Device Co., Ltd., Shenzhen (CN)

(72) Inventors: Wei Zhai, Shenzhen (CN); Cheng Jiang, Shenzhen (CN)

(21) Appl. No.: 17/801,636

(22) PCT Filed: Feb. 28, 2022
(86) PCT No.: PCT/CN2022/078494

§ 371 Date: Aug. 23, 2022

(30) Foreign Application Priority Data
Jun. 30, 2021 (CN) 202110739400.4

(51) Int. Cl. G01R 29/08

(52) U.S. Cl. CPC G01R 29/0878

(57) ABSTRACT

This application provides a probe structure for radio frequency testing, and a radio frequency test apparatus and system, and relates to the field of radio frequency testing, to resolve the problem of a waste of space in a terminal caused by that a relatively large volume of a probe cylinder of a probe structure in radio frequency testing requires a relatively large avoidance space during testing to avoid the probe cylinder. This application provides a probe structure for radio frequency testing, including a housing, a medium, a first test probe, and a second test probe. The medium is arranged in the housing, the first test probe is arranged in the medium, a signal end of the first test probe is connected to a signal line of the radio frequency connector, and the first test probe is coaxial with the medium. The second test probe is arranged on the housing, and test ends of the first test probe and the second test probe are located at a same end of the housing. A length by which the first test probe protrudes out of the housing and/or the medium is a first preset length, a length by which the second test probe protrudes out of the housing is a second preset length, and the first preset length and the second preset length are both greater than a height of an avoidance device.

This application claims priority to Chinese Patent Application No. 202110739400.4, filed with China National Intellectual Property Administration on Jun. 30, 2021 and entitled “PROBE STRUCTURE FOR RADIO FREQUENCY TESTING, AND RADIO FREQUENCY TEST APPARATUS AND SYSTEM”, which is incorporated herein by reference in its entirety.

### TECHNICAL FIELD

This application relates to the field of radio frequency testing, and in particular, to a probe structure for radio frequency testing, and a radio frequency test apparatus and system.

### BACKGROUND

During radio frequency testing, common test instruments cannot be directly connected to a device under test, and need to be connected to a product or board under test by a probe structure, and then signals are imported to the test instruments.

In the prior art, during testing on a PCB board or substrate on a product, because the test probe is mounted on the probe cylinder, the probe cylinder in the prior art is generally thick, and when the test probe comes into contact with the PCB board or substrate, the probe cylinder is very close to the PCB board or substrate, a large avoidance space needs to be reserved on the PCB board or the substrate to avoid the probe cylinder, resulting in a great waste of space in a terminal.

### SUMMARY

Embodiments of this application provide a probe structure for radio frequency testing, and a radio frequency test apparatus and system, to resolve the problem of a waste of space in a terminal caused by that a relatively large volume of a probe cylinder of a probe structure in radio frequency testing requires a relatively large avoidance space during the testing to avoid the probe cylinder. In this application, during radio frequency testing, the occupation of the layout space on a PCB board or substrate can be reduced, and the space utilization of the PCB board or substrate is improved.

To achieve the foregoing objectives, this application adopts the following technical solutions:

According to a first aspect, a probe structure for radio frequency testing is provided, and is configured to couple a radio frequency detection signal coupled out from a transmission line of a radio frequency connector into a circuit under test. The structure includes a housing, a medium, a first test probe, and a second test probe. The medium is arranged in the housing, the first test probe is arranged in the medium, a signal end of the first test probe is connected to a signal line of the radio frequency connector, and the first test probe is coaxial with the medium. The second test probe is arranged on the housing, and a test end of the first test probe and a test end of the second test probe are located at a same end of the housing. A length by which the first test probe protrudes out of the housing and/or the medium is a first preset length, a length by which the second test probe protrudes out of the housing is a second preset length, and the first preset length and the second preset length are both greater than a height of an avoidance device.

On this basis, the first test probe is mainly configured to conduct a radio frequency signal. The first test probe is arranged to be coaxial with the medium, to reduce the impedance during radio frequency testing. The first test probe and the second test probe are arranged to protrude out of the housing by specific lengths, and the lengths by which the first test probe and the second test probe protrude out of the housing are both greater than the height of the avoidance device. In this way, the housing can be prevented from interfering with the avoidance device during radio frequency testing, so that the avoidance device can be flexibly arranged on the to-be-tested main board without leaving a specific avoidance space on the to-be-tested main board to avoid the housing, which is beneficial to improving the space utilization of the to-be-tested main board.

In one possible design of the first aspect, the first test probe is an elastic probe, and the second test probe is a rigid probe.

On this basis, an elastic probe is arranged as the first test probe, and a rigid probe is arranged as the second test probe, which is beneficial to improving the stability of contact between the first test probe and the to-be-tested main board and between the second test probe and the to-be-tested main board, thereby implementing good electrical conductivity.

In one possible design of the first aspect, the first test probe and the second test probe are arranged in parallel. The two test probes are arranged in parallel, which is beneficial to manufacturing and machining, and is also beneficial to implementing connections between the two test probes and the to-be-tested main board without occupying a relatively large space on the to-be-tested main board.

In one possible design of the first aspect, the first test probe and the second test probe are both in a natural state, and the first preset length is greater than the second preset length.

On this basis, the first preset length is set to be greater than the second preset length in the natural state, which is beneficial to implementing the good contact between the two test probes and the to-be-tested main board.

In one possible design of the first aspect, the top end of the medium is flush with the top end of the housing, and the bottom end of the medium is flush with the bottom end of the housing.

According to a second aspect, this application provides a radio frequency test apparatus. The device includes a to-be-tested main board and the probe structure for radio frequency testing according to the first aspect. A first patch and a second patch are arranged on a board surface of the to-be-tested main board. A test end of a first test probe is electrically connected to the first patch. A test end of the second test probe is electrically connected to the second patch. A compensation board is arranged in the to-be-tested main board, and the compensation board is arranged directly facing the first patch.

On this basis, the compensation board is arranged, and the compensation board is arranged directly facing the first patch to form a plate capacitor, to compensate for the impedance generated by partial probe bodies of the first test probe and the second test probe protruding out of the housing, which is beneficial to improving the broadband matching effect of the radio frequency test apparatus.

In one possible design of the second aspect, a grounding board is also arranged in the to-be-tested main board, the second patch is electrically connected to the grounding board, and the compensation board and the grounding board are integrally formed.

In one possible design of the second aspect, when the probe structure for radio frequency testing is in a test state, the first test probe is in a compressed state, and a first preset length is equal to a second preset length.

In one possible design of the second aspect, the compensation board is in a shape of a rectangle, a circle, or a regular polygon.

In one possible design of the second aspect, a size of the compensation board is positively correlated with the second preset length.

According to a third aspect, this application provides a radio frequency test system, including a to-be-tested main board, a radio frequency connector, a radio frequency cable, a radio frequency tester, and a probe structure for radio frequency testing. A test end of the probe structure for radio frequency testing is electrically connected to the to-be-tested main board. The probe structure for radio frequency testing is electrically connected to the radio frequency tester by the radio frequency connector and the radio frequency cable. The probe structure for radio frequency testing includes: a housing, a medium, a first test probe, and a second test probe. The medium is arranged in the housing, the first test probe is arranged in the medium, a signal end of the first test probe is connected to a signal line of the radio frequency connector, and the first test probe is coaxial with the medium. The second test probe is arranged on the housing, and a test end of the first test probe and a test end of the second test probe are located at a same end of the housing. A length by which the first test probe protrudes out of the housing and/or the medium is a first preset length, a length by which the second test probe protrudes out of the housing is a second preset length, and the first preset length and the second preset length are both greater than a height of an avoidance device.

In one possible design of the first aspect, the first test probe is an elastic probe, and the second test probe is a rigid probe.

In one possible design of the first aspect, the first test probe and the second test probe are arranged in parallel.

In one possible design of the first aspect, the first test probe and the second test probe are both in a natural state, and the first preset length is greater than the second preset length.

In one possible design of the first aspect, the top end of the medium is flush with the top end of the housing, and the bottom end of the medium is flush with the bottom end of the housing.

It can be understood that, for the beneficial effects achieved by the radio frequency test apparatus provided in the second aspect and the radio frequency test system provided in the third aspect, reference may be made to the beneficial effects in the first aspect and any possible design thereof. Details are not described herein again.

### BRIEF DESCRIPTION OF DRAWINGS

FIG. 1 is a partial schematic diagram of a connection between a probe structure for radio frequency testing and a to-be-tested main board according to an embodiment of this application;

FIG. 2 is a partial schematic structural diagram of the to-be-tested main board shown in FIG. 1;

FIG. 3 is a schematic diagram of a connection of a radio frequency test system according to an embodiment of this application;

FIG. 4 is a schematic structural diagram of a probe structure for radio frequency testing connected to a radio frequency connector according to an embodiment of this application;

FIG. 5 is a bottom view of a probe structure for radio frequency testing according to an embodiment of this application;

FIG. 6 is a schematic diagram of an avoidance space that needs to be reserved on a circuit board in the prior art;

FIG. 7 is a schematic diagram of a space near a patch on a circuit board in a radio frequency test apparatus according to an embodiment of this application;

FIG. 8 is a schematic structural diagram 1 of a radio frequency test apparatus being connected to a radio frequency connector according to an embodiment of this application;

FIG. 9 is a schematic structural diagram 2 of a radio frequency test apparatus connected to a radio frequency connector according to an embodiment of this application;

FIG. 10 is a top view of a radio frequency test apparatus according to an embodiment of this application;

FIG. 11 is a partial schematic 3D diagram of a radio frequency test apparatus according to an embodiment of this application;

FIG. 12 is an impedance position diagram of a radio frequency test apparatus without a compensation board according to an embodiment of this application; and

FIG. 13 is an impedance position diagram of a radio frequency test apparatus with a compensation board according to an embodiment of this application.

In the figures: 1. Housing; 2. Medium; 3. First test probe; 4. Second test probe; 5. Radio frequency connector; 6. To-be-tested main board; 7. First patch; 8. Second patch; 9. Compensation board; 10. Grounding board; 11. Avoidance device; 12. Impedance transformer; 13. Directional coupler; and 14. Radio frequency tester.

### DESCRIPTION OF EMBODIMENTS

The technical solutions of this application are described below with reference to the accompanying drawings.

In the embodiments of this application, the terms, such as “exemplary” or “example”, are used to represent giving an example, an illustration, or a description. Any embodiment or design scheme described by using “exemplary” or “for example” in the embodiments of this application should not be construed as being more preferred or having more advantages than another embodiment or design scheme. In particular, use of the terms, such as “exemplary” or “for example”, is intended to present the related concept in a specific implementation.

In the embodiments of this application, the terms “first” and “second” are used merely for the purpose of description, and shall not be construed as indicating or implying relative importance or implying a quantity of indicated technical features. Therefore, a feature defined by “first” or “second” can explicitly or implicitly includes one or more features.

It should be understood that the terms used in description of the various examples in this specification are intended for describing specific examples only rather than limiting them. As used in the descriptions of the various examples, singular forms “one” (“a” or “an”) and “the” are intended to include plural forms as well, unless otherwise explicitly indicated in the context.

In this application, “at least one” means one or more, and “a plurality of” means two or more. “At least one of the following” or a similar expression thereof refers to any combination of these items, including one item or any combination of a plurality of items. For example, at least one of a, b, or c may represent: a, b, c, a-b, a-c, b-c, or a-b-c, where a, b, and c may be singular or plural.

It should also be understood that the term “and/or” used in this specification refers to and includes any and all possible combinations of one or more of the associated listed items. The term “and/or” describes an association relationship for describing associated objects and represents that three relationships may exist. For example. A and/or B may represent the following three cases: Only A exists, both A and B exist, and only B exists. In addition, the character “/” in this application generally indicates an “or” relationship between the associated objects.

It should also be understood that, in this application, unless otherwise explicitly specified or defined, the term “connection” should be understood in a broad sense. For example, the “connection” may be a fixed connection, a slidable connection, a detachable connection, or integration: or may be a direct connection, or an indirect connection through an intermediary.

It should also be understood that the term “include” (also referred to as “includes”, “including”. “comprises”, and/or “comprising”), when used in this specification, specifies the existence of stated features, integers, steps, operations, elements, and/or components, but does not exclude the existence or addition of one or more other features, integers, steps, operations, elements, components, and/or groups thereof.

It should be understood that “an embodiment”, “another embodiment”, or “one possible design” mentioned throughout the specification means that particular features, structures, or properties related to the embodiments or implementations are included in at least one embodiment of this application. Therefore, “in an embodiment of this application”, “in another embodiment of this application”, or “one possible design” that appears throughout the specification may not necessarily refer to the same embodiment. In addition, the particular features, structures, or properties may be combined in one or more embodiments in any proper manner.

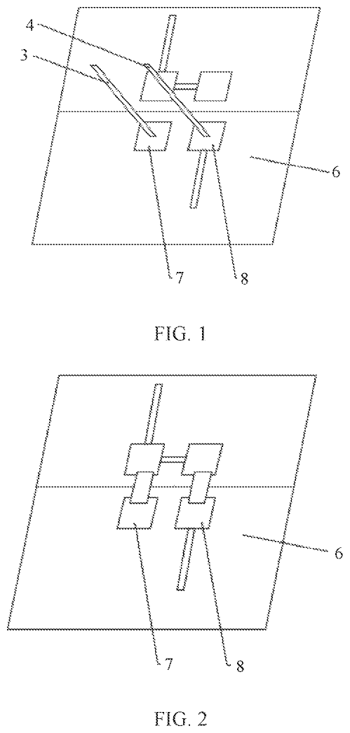

To resolve the problem of a waste of space in a terminal caused by that a relatively large volume of a probe cylinder of a probe structure in radio frequency testing requires a relatively large avoidance space during the testing to avoid the probe cylinder in the prior art, the embodiments of this application provide a probe structure for radio frequency testing, to reduce the occupation of the layout space on a PCB board or substrate during a radio frequency testing, and improve the space utilization of the PCB board or substrate. The embodiments of this application are described below with reference to FIG. 1 to FIG. 13.

An embodiment of this application provides a probe structure for radio frequency testing, which is connected to a to-be-tested main board 6, and is configured to couple a radio frequency detection signal coupled out from a transmission line of a radio frequency connector 5 into a circuit under test, and import the radio frequency detection signal into a corresponding radio frequency tester 14 for detection. The to-be-tested main board 6 in the embodiments of this application may be another product board such as a PCB board or a chip substrate. In this embodiment of this application, the PCB board is used as an example for description.

FIG. 1 is a partial schematic diagram of a connection between a probe structure for radio frequency testing and a to-be-tested main board 6 according to an embodiment of this application, which is specifically a schematic diagram of contact between a test probe in the probe structure for radio frequency testing and a part of the PCB board. The test probe in this embodiment of this application includes a first test probe 3 and a second test probe 4. The to-be-tested main board 6 shown in FIG. 1 is a PCB board, which may be configured to connect to an antenna. An upper half part of the PCB board is clear, and a patch and a radio frequency circuit are arranged at a lower part. The first test probe 3 and the second test probe 4 in the probe structure for radio frequency testing are correspondingly connected to a first patch 7 and a second patch 8 on the PCB board respectively, so that the probe structure can be connected to the radio frequency circuit of the PCB board.

In this embodiment of this application, the first patch 7 and the second patch 8 are arranged on the PCB board, and then are connected to the test probes in the probe structure. In this way, the first patch 7 and the second patch 8 can be reused after the radio frequency testing is completed. FIG. 2 is a partial schematic structural diagram of the to-be-tested main board 6 shown in FIG. 1, which may be a partial schematic structural diagram of a PCB board in this embodiment of this application. The PCB board may be connected to an antenna. An upper half part of the PCB board may be used as a clearance area of the antenna. After radio frequency testing is completed, the first patch 7 and the second patch 8 may be electrically connected to connecting elements in the clearance area. For a connection manner, reference may be made to FIG. 2, and specifically, a connection may be achieved by welding. The first patch 7 and the second patch 8 occupy a small space on the PCB board, have low costs, and can be used as elements required on the PCB board. The probe structure provided in this embodiment of this application may be connected to the PCB board by the first patch 7 and the second patch 8, thereby reducing the connection cost while reducing the occupation of space on the PCB board.

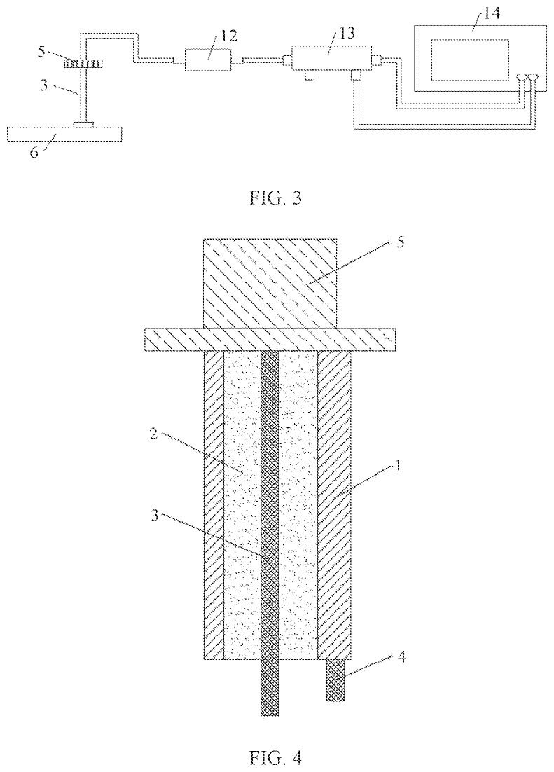

The probe structure for radio frequency testing provided in this embodiment of this application is specifically applied to a radio frequency test system. FIG. 3 is a schematic diagram of a connection of a radio frequency test system according to an embodiment of this application. The radio frequency test system includes a to-be-tested main board 6, a probe structure for radio frequency testing, a radio frequency connector 5, a radio frequency cable, and a radio frequency tester 14. A test probe in the probe structure for radio frequency testing is configured to come into contact with and electrically connect to the to-be-tested main board 6, thereby achieving the conduction of radio frequency signals. The probe structure is connected to the radio frequency tester 14 by the radio frequency connector 5 and the radio frequency cable, so that the radio frequency signals are transmitted to the radio frequency tester 14, and are tested and analyzed by the radio frequency tester 14. In addition, a directional coupler 13 and the like may be added between the probe structure and the radio frequency tester 14. The directional coupler 13 may be configured to isolate, separate, and mix signals, to improve the indicators, such as the directionality, a standing wave ratio, a coupling degree, and an insertion loss, of radio frequency signals. An impedance transformer 12 may also be added between the radio frequency connector 5 and the directional coupler 13, and the impedance transformer 12 can be configured to adjust the impedance of the probe structure for radio frequency testing.

The probe structure for radio frequency testing and the radio frequency test apparatus in this embodiment of this application are described below.

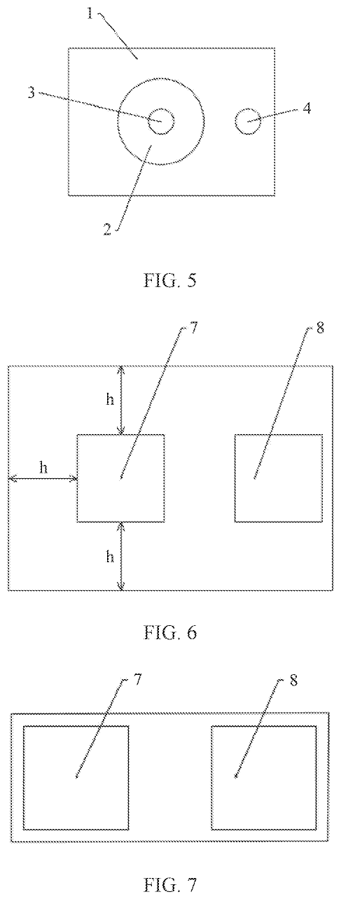

FIG. 4 is a schematic diagram of a probe structure for radio frequency testing according to an embodiment of this application, and FIG. 5 is a bottom view of a probe structure for radio frequency testing according to an embodiment of this application. As shown in FIG. 4 and FIG. 5, the structure for radio frequency testing provided in this embodiment of this application includes a housing 1, a medium 2, and a test probe. In this embodiment, the test probe includes a first test probe 3 and a second test probe 4. The medium 2 is arranged in the housing 1, the first test probe 3 is arranged in the medium 2, a signal end of the first test probe 3 is connected to a signal line of the radio frequency connector 5, and the first test probe 3 is coaxial with the medium 2. The second test probe 4 is arranged on the housing 1, and a test end of the first test probe 3 and a test end of the second test probe 4 are located at a same end of the housing 1. A length by which the first test probe 3 protrudes out of the housing 1 and/or the medium 2 is a first preset length, a length by which the second test probe 4 protrudes out of the housing 1 is a second preset length, and the first preset length and the second preset length are both greater than a height of an avoidance device 11.

In this embodiment of this application, the housing 1 is a support body of the entire probe structure for radio frequency testing, may provide support for other components of the probe structure for radio frequency testing, and may provide protection to other components. When the probe structure for radio frequency testing performs testing, the housing 1 may also be used as a connecting piece for connecting to other instruments or structures. For example, when connecting to the radio frequency connector 5, the housing 1 may be grounded as a direct connecting piece between the to-be-tested main board 6 and the radio frequency connector 5.

It should be noted that, a shape of the housing 1 is not limited in this embodiment of this application, and the housing 1 may be a housing 1 in a shape of a cylinder, a polygonal prism, a rectangular parallelepiped, a cube, or the like. A hollow portion is provided in the housing 1, and the hollow portion is configured to mount the medium 2. Specifically, the hollow portion in this application is a through hole, and the medium 2 is arranged in the through hole. The medium 2 is in a shape of a cylinder, and an outer diameter of the medium 2 is the same as a diameter of the through hole, so that the entire medium 2 can fill up the through hole in the housing 1.

The first test probe 3 is arranged in the medium 2, and an axis of the first test probe 3 coincides with an axis of the medium 2. In this way, the first test probe 3 and the medium 2 form a coaxial structure. Setting the first test probe 3 and the medium 2 to be a coaxial structure is beneficial to adjusting the characteristic impedance of the first test probe 3 during testing. There is an interference fit between the first test probe 3 and the medium 2, to prevent the first test probe 3 from falling off the medium 2. Specifically, a through hole may be provided on the medium 2, the first test probe 3 is arranged in the through hole, and an outer diameter of the first test probe 3 is slightly greater than a diameter of the through hole, to form the interference fit. One end of the first test probe 3 close to the radio frequency connector 5 is a signal end, and is configured to connect to a signal line of the radio frequency connector 5; and an other end is a test end, and is configured to come into contact with the to-be-tested main board 6, and transmit a radio frequency signal to the to-be-tested main board 6.

In this embodiment of this application, the first test probe 3 is mainly configured to transmit the radio frequency signal, and the second test probe 4 is mainly configured for ground connection. The second test probe 4 is fixedly arranged on the housing 1, the housing 1 is connected to a grounding line in the radio frequency connector 5. During testing, the second test probe 4 is in contact with a grounding board 10 on the to-be-tested main board 6. The second test probe 4 may be connected to the housing 1 in a manner such as welding or screwing, and the second test probe 4 and the housing 1 may also be an integrally formed structure. For example, the second test probe 4 may be milled directly on the housing 1.

An end of the second test probe 4 in contact with the to-be-tested main board 6 is a test end thereof, and a test end of the first test probe 3 and the test end of the second test probe 4 are arranged at a same end of the housing 1. Such arrangement helps the test end of the first test probe 3 and the test end of the second test probe 4 to simultaneously come into contact with the to-be-tested main board 6, to implement electrical connections. In this embodiment of this application, the same end of the housing 1 refers to an end of the housing 1 close to the to-be-tested main board 6.

In this embodiment of this application, when the first test probe 3 and the second test probe 4 are arranged, the first test probe 3 and the second test probe 4 are arranged in parallel, and an axis of the first test probe 3 and an axis of the second test probe 4 are both arranged in parallel with a centerline of the housing 1. That is, when the probe structure is placed vertically, the first test probe 3 and the second test probe 4 may come into vertical contact with the to-be-tested main board 6 that is placed horizontally, to prevent the first test probe 3 and the second test probe 4 from being damaged due to an excessive contact force in a contact process.

Because the first test probe 3 is fixed on the housing 1 by the medium 2, and the second test probe 4 is directly connected to the housing 1, during radio frequency testing, lengths by which the first test probe 3 and the second test probe 4 protrude out of the housing 1 affect a distance between the housing 1 and the to-be-tested main board 6. However, a cross section of the housing 1 is generally large. When the housing 1 is relatively close to the to-be-tested main board 6, a specific space needs to be reserved on the to-be-tested main board 6, and no device can be arranged in the space. When the housing 1 is relatively close to the to-be-tested main board 6, reference may be made to FIG. 6, which is a schematic diagram of an avoidance space that needs to be reserved on a circuit board in the prior art. As shown in FIG. 6, the first patch 7 and the second patch 8 are arranged on the to-be-tested main board 6. A space with a length of h needs to be reserved around the first patch 7 and the second patch 8, and the value of h needs to be determined according to a specific size of the housing 1. It should be noted that, FIG. 6 merely illustrates one case, and it is unnecessary to uniformly reserve the space with the length of h around the first patch 7 or the second patch 8. Alternatively, a space reserved at one side of the first patch 7 or the second patch 8 may be larger than a space reserved at an other side. The reserved space needs to be specifically determined according to the size of the housing 1.

In this embodiment of this application, when the first test probe 3 and the second test probe 4 are arranged, a length by which the first test probe 3 protrudes out of the housing 1 and/or the medium 2 is set, where the length is a first preset length. A length by which the second test probe 4 protrudes out of the housing 1 is set, where the length is a second preset length. In addition, the first preset length and the second preset length are designed to be greater than a height of an avoidance device 11. In this way, the distance between the housing 1 and the to-be-tested main board 6 is greater than the height of the avoidance device 11 on the to-be-tested main board 6. Therefore, it is unnecessary to arrange a reserved space on the to-be-tested main board 6, and corresponding devices can be arranged on the to-be-tested main board 6 as required without worrying that the housing 1 interferes with the devices.

FIG. 7 is a schematic diagram of a space near a patch on a circuit board in a radio frequency test apparatus according to an embodiment of this application. As shown in FIG. 7, it is unnecessary to leave an avoidance space around the first patch 7 and the second patch 8 on the to-be-tested main board 6, and devices can be arranged around the first patch 7 and the second patch 8 as needed. When the first preset length and the second preset length are both greater than the height of the avoidance device 11, because the housing 1 does not interfere with the avoidance device 11 on the to-be-tested main board 6, the devices can be arranged around the first patch 7 and the second patch 8.

It should be noted that, when an end of the medium 2 close to the to-be-tested main board 6 protrudes out of the housing 1, the first preset length refers to a length by which the test end of the first test probe 3 protrudes out of the medium 2. When the end of the medium 2 close to the to-be-tested main board 6 is located in the housing 1, the first preset length refers to a length by which the test end of the first test probe 3 protrudes out of the housing 1. When the end of the medium 2 close to the to-be-tested main board 6 is flush with an end of the housing 1 close to the to-be-tested main board 6, the first preset length may be the length by which the test end of the first test probe 3 protrudes out of the housing 1 or the length by which the test end of the first test probe 3 protrudes out of the medium 2. In this embodiment of this application, two ends of the medium 2 are flush with two ends of the housing 1. As shown in FIG. 4, a top end of the medium 2 is flush with a top end of the housing 1, and a bottom end of the medium 2 is flush with a bottom end of the housing 1. In addition, the signal end of the first test probe 3 is also kept flush with the top end of the medium 2 and the top end of the housing 1. Such arrangement is convenient for manufacturing, and is also convenient for connecting to the radio frequency connector 5. The bottom end of the medium 2 is made flush with the bottom end of the housing 1, so that the first test probe 3 in the housing 1 is completely wrapped by the medium 2, which is beneficial to reducing the impedance while preventing the medium 2 from protruding out of the housing 1 and interfering with the devices on the to-be-tested main board 6 during testing.

In this embodiment of this application, the first test probe 3 is an elastic probe, and the second test probe 4 is a rigid probe. “The first test probe 3 is an elastic probe” means that after the test end of the first test probe 3 comes into contact with the first patch 7 on the to-be-tested main board 6, and after the first test probe 3 is subjected to a force in an axial direction thereof, the first preset length may vary according to a magnitude of the force. For example, when the housing 1 moves toward the to-be-tested main board 6, and the housing 1 continues to move after the test end of the first test probe 3 comes into contact with the first patch 7 on the to-be-tested main board 6, the first preset length is shortened as the housing 1 continues to move. After the test end of the first test probe 3 comes into contact with the first patch 7 on the to-be-tested main board 6, when the first test probe 3 is in a compressed state, if the housing 1 moves in a direction away from the to-be-tested main board 6, the first preset length is lengthened with the movement of the housing 1 because the first test probe 3 has elasticity. “The second test probe 4 is a rigid probe” means that the second preset length does not vary after the second test probe 4 is stressed.

The first test probe 3 and the second test probe 4 are arranged in parallel. Specifically, the first test probe 3 and the second test probe 4 may both maintain vertical relationships with the to-be-tested main board 6 during the test. In this way, a distance between the first test probe 3 and the second test probe 4 can be controlled without occupying an excessive space on the to-be-tested main board 6. The first test probe 3 and the second test probe 4 are arranged to keep in a vertical state with respect to the to-be-tested main board 6, so that the test probes are not deformed or broken because the first test probe 3 and the second test probe 4 are overstressed during contact with the to-be-tested main board 6, and can come into contact with the to-be-tested main board 6 with the shortest probe bodies.

In this embodiment of this application, when the first test probe 3 and the second test probe 4 are both in a natural state, the first preset length is greater than the second preset length. During the testing, when the housing 1 gradually approaches the to-be-tested main board 6, because the first preset length is greater than the second preset length, the first test probe 3 comes into contact with the to-be-tested main board 6 before the second test probe 4. Because the first test probe 3 is a spring probe, the housing 1 continues approaching the to-be-tested main board 6 after the first test probe 3 comes into contact with the to-be-tested main board 6, and the first test probe 3 is compressed until the second test probe 4 comes into contact with the to-be-tested main board 6. Because the second test probe 4 is a rigid probe, after the second test probe 4 comes into contact with the to-be-tested main board 6, the housing 1 stops moving. In this case, the first test probe 3 and the second test probe 4 both maintain good contact with the to-be-tested main board 6. Because the first test probe 3 and the second test probe 4 are arranged in parallel, the first preset length is equal to the second preset length.

The natural state described above refers to a state when the first test probe 3 and the second test probe 4 are not subjected to an external force. When the probe structure for radio frequency testing is not in a test state, that is, when the first test probe 3 and the second test probe 4 are not in contact with the to-be-tested main board 6, the state at this time is the natural state. Because the first test probe 3 is an elastic probe, and the first preset length is set to be greater than the second preset length, the second test probe 4 may be made just in contact with the to-be-tested main board 6. In this case, the first test probe 3 is compressed and comes into contact with the to-be-tested main board 6. In this way, the two test probes simultaneously maintain good contact with the to-be-tested main board 6. In this embodiment of this application, the first preset length may also be set to be equal to the second preset length. However, in actual production, due to a machining error, it is difficult for the first preset length to be exactly equal to the second preset length, resulting in that it is difficult for the first test probe 3 and the second test probe 4 to simultaneously come into contact with the to-be-tested main board 6, which affects the test effect. Therefore, setting the first preset length to be equal to the second preset length requires extremely high machining accuracy for the first test probe 3 and the second test probe 4.

Because the first test probe 3 protrudes out of the housing 1 by a first preset length, and the second test probe 4 protrudes out of the housing 1 by a second preset length, the two test probes both protrude out of the housing 1 by specific lengths. Such arrangement is beneficial to reducing the avoidance space on the to-be-tested main board 6, but the test probes protruding out of the housing 1 produce obvious inductive impedance during testing, which deteriorates the high-frequency signal impedance, and affects the test effect. To resolve this problem, an embodiment of this application further provides a radio frequency test apparatus.

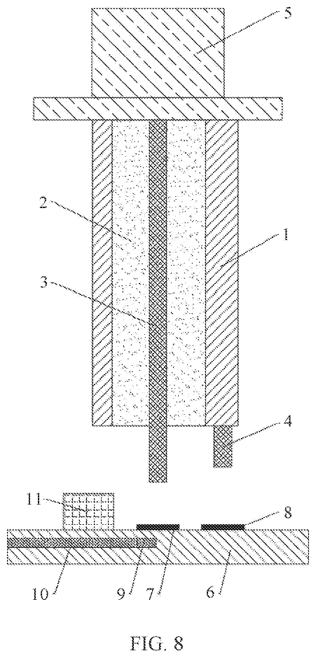

FIG. 8 is a schematic structural diagram 1 of a radio frequency test apparatus connected to a radio frequency connector 5 according to an embodiment of this application. As shown in FIG. 8, the device includes a to-be-tested main board 6 and the probe structure for radio frequency testing according to any of the foregoing embodiments. A first patch 7 and a second patch 8 are arranged on a board surface of the to-be-tested main board 6. A test end of a first test probe 3 is electrically connected to the first patch 7. A test end of a second test probe 4 is electrically connected to the second patch 8. A compensation board 9 is arranged in the to-be-tested main board 6, the compensation board 9 is electrically connected to the second test probe 4, and the compensation board 9 is arranged directly facing the first patch 7. FIG. 8 shows a state in which the probe structure for radio frequency testing is not in contact with the to-be-tested main board 6.

The first patch 7 and the second patch 8 are configured to electrically connect to the first test probe 3 and the second test probe 4 respectively, to implement signal transmission. The first patch 7 and the second patch 8 may be arranged in a shape such as a circle or a square. In this embodiment of this application, the first patch 7 and the second patch 8 have the same size and the same material. In this embodiment of this application, the first test probe 3 is mainly configured to transmit a radio frequency signal, and the second test probe 4 is mainly configured for ground connection. Because the first test probe 3 and the second test probe 4 protrude out of the housing 1 by specific distances, the impedance of the high-frequency signal is deteriorated by a relatively long probe-like structure during the test. To improve the impedance produced by the test probe protruding out of the housing 1, this embodiment of this application provides a compensation board 9 in the to-be-tested main board 6. The compensation board 9 is arranged directly facing the first patch 7. The compensation board 9 and the first patch 7 are made of a metal material, for example, may be made of a copper sheet. Because the first patch 7 is electrically connected to the first test probe 3, the compensation board 9 is electrically connected to the second test probe 4, and the compensation board 9 is arranged directly facing the first patch 7, a plate capacitor is formed between the compensation board 9 and the first patch 7, and produces a specific capacitive impedance to compensate for the inductive impedance produced by the first test probe 3 and the second test probe 4, thereby implementing the broadband matching.

It should be noted that, the capacitive coupling produced by the compensation board 9 and the first patch 7 may be adjusted by adjusting a directly facing area between the compensation board 9 and the first patch 7 and a distance between the compensation board 9 and the first patch 7. However, the inductive impedance produced by the first test probe 3 and the second test probe 4 is related to the first preset length and/or the second preset length. To implement the broadband matching during the radio frequency testing, in a designing process, the directly facing area between the compensation board 9 and the first patch 7 and the distance between the compensation board 9 and the first patch 7 may be determined according to the first preset length and the second preset length.

When the radio frequency test apparatus performs radio frequency testing, the first test probe 3 and the second test probe 4 both need to come into contact with the to-be-tested main board 6, to implement electrical connections. In this embodiment of this application, the first test probe 3 is an elastic probe, and the second test probe 4 is a rigid probe. In an initial state, that is, when the structure for radio frequency testing is not in contact with the to-be-tested main board 6, the first preset length is greater than the second preset length. Therefore, during the radio frequency testing, when the housing 1 is driven to move in the direction of approaching the to-be-tested main board 6, because the first preset length is greater than the second preset length, when the first test probe 3 comes into contact with the first patch 7 on the to-be-tested main board 6, the second test probe 4 is not in contact with the second patch 8 at this time. Then, the to-be-tested main board 6 continues moving in the direction of approaching the to-be-tested main board 6. The first test probe 3 is compressed due to elasticity, so that the first preset length is gradually shortened until the second test probe 4 comes into contact with the second patch 8. At this time, the first test probe 3 and the second test probe 4 are both in contact with the to-be-tested main board 6.

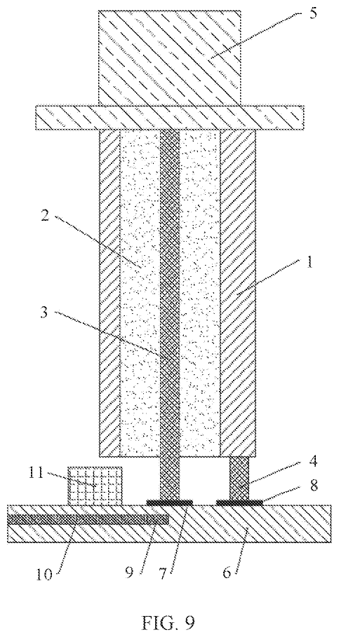

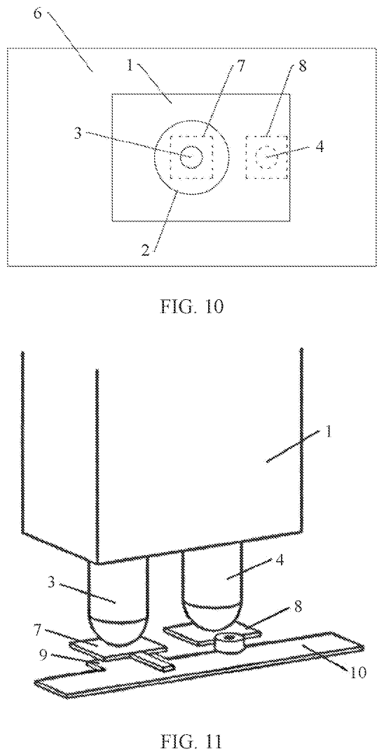

FIG. 9 is a schematic structural diagram 2 of a connection between a radio frequency test apparatus and a radio frequency connector 5 according to an embodiment of this application, FIG. 10 is a top view of a radio frequency test apparatus according to an embodiment of this application, and FIG. 9 shows a state in which the probe structure for radio frequency testing is in contact with the to-be-tested main board 6. As shown in FIG. 9 and FIG. 10, because the first patch 7 and the second patch 8 have the same size, the first preset length after the first test probe 3 is compressed is equal to the second preset length. When being set, a size of the compensation board 9 and a distance between the compensation board 9 and the first patch 7 may be determined according to a value of the second preset length. That is, the size of the compensation board 9 and the distance between the compensation board 9 and the first patch 7 are both related to the second preset length. A specific calculation process belongs to the prior art. Details are not described in the embodiments of this application.

In this embodiment of this application, the second test probe 4 is mainly configured for ground connection. Therefore, the second patch 8 connected to the second test probe 4 is also connected to the grounding board 10 on the to-be-tested main board 6. FIG. 11 is a partial schematic 3D diagram of a radio frequency test apparatus according to an embodiment of this application. As shown in FIG. 11, a grounding board 10 is arranged in the to-be-tested main board 6, and the grounding board 10 is a metal layer, which may be specifically a copper sheet. The second patch 8 is electrically connected to the metal layer, to implement the ground connection of the second test probe 4. Specifically, the second patch 8 may be connected to the metal layer through a through hole. The grounding board 10 and the compensation board 9 are arranged in the to-be-tested main board 6, and the grounding board 10 and the compensation board 9 are made of metal and are both electrically connected to the second test probe 4. Therefore, the grounding board 10 and the compensation board 9 may be integrally formed.

As shown in FIG. 11, the grounding board 10 and the compensation board 9 are a metal sheet integrally formed, which is specifically a copper piece integrally formed. The compensation board 9 is an outwardly protruding portion of the entire metal sheet, and the protruding portion is arranged directly facing the first patch 7. “Arranged directly facing” means that the compensation board 9 and the first patch 7 are arranged in parallel, and a directly facing area between the compensation board 9 and the first patch 7 is the largest. In FIG. 11, the compensation board 9 is located directly below the first patch 7. In this embodiment of this application, the compensation board 9 may be in a shape of a square, a rectangle, a circle, a regular polygon, or the like, and the shape of the compensation board 9 is not limited in this embodiment of this application. The grounding board 10 may be in a shape of a rectangle, a square, or the like, which is generally determined according to the shape of the to-be-tested main board 6.

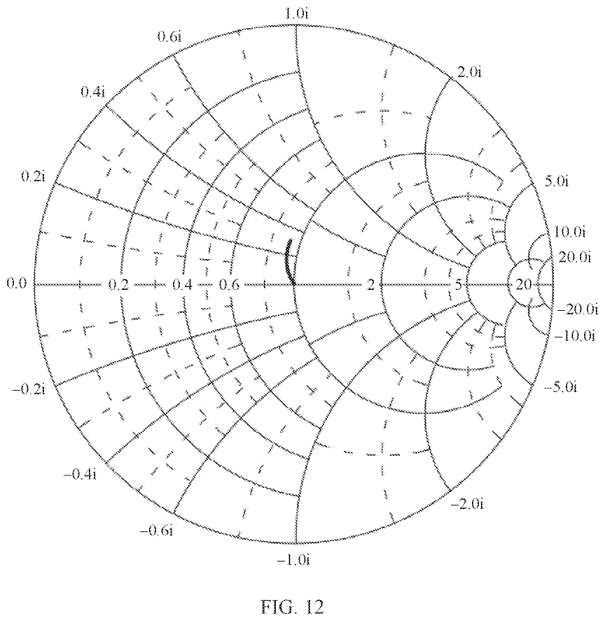

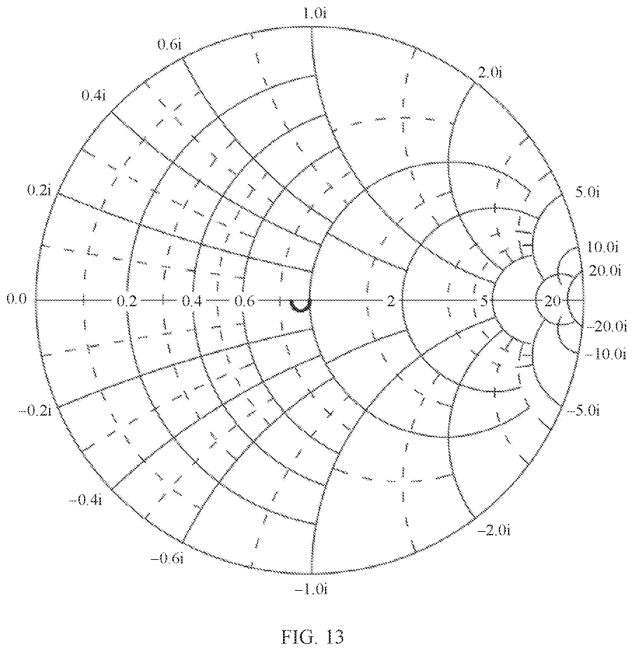

In this embodiment of this application, before and after the compensation board 9 is arranged, the echo loss of the radio frequency test apparatus is tested. FIG. 12 is a diagram of an impedance position of a radio frequency test apparatus without a compensation board 9 according to an embodiment of this application. It can be seen from a curve in FIG. 12 that, when the compensation board 9 is not arranged, the radio frequency test apparatus presents an obvious inductive impedance. FIG. 13 is a diagram of an impedance position of a radio frequency test apparatus with a compensation board 9 according to an embodiment of this application. As shown in FIG. 13, a curve in FIG. 13 is closer to a center and a radius is relatively small, and the broadband matching effect of the curve in FIG. 13 is significantly improved compared with that shown in FIG. 12, indicating that the impedance of the radio frequency test apparatus is significantly improved after the compensation board 9 is arranged.

The foregoing descriptions are merely specific implementations of this application, but are not intended to limit the protection scope of this application. Any variation or replacement readily figured out by a person skilled in the art within the technical scope disclosed in this application shall fall within the protection scope of this application.

The embodiments in this specification are described in a progressive manner. Each embodiment focuses on a difference from other embodiments. Refer to the embodiments for same or similar parts in the embodiments.

Although exemplary embodiments of the embodiments of this application have been described, a person skilled in the art can make other changes and modifications to these embodiments once they know the basic creative concept of this application. Therefore, the scope of protection of this application includes the exemplary embodiments and all changes and modifications falling within the scope of the embodiments of this application.

The foregoing describes a probe structure for radio frequency testing, and a radio frequency test apparatus and system provided in this application in detail. The principles and embodiments of this application are described by applying specific examples in this specification. The foregoing descriptions are merely used to help understand the methods and the core ideas of this application. In addition, a person of ordinary skill in the art can make variations to this application in terms of the specific implementations and application scopes according to the ideas of this application. Therefore, the content of this specification shall not be construed as limiting this application.

1. A probe structure for radio frequency testing, configured to provide a radio frequency detection signal from a transmission line of a radio frequency connector into a circuit under test, the probe structure for radio frequency testing comprising:
a housing;
a medium arranged in the housing;
a first test probe arranged in the medium and coaxial with the medium, wherein a signal end of the first test probe is configured to connect to a signal line of the radio frequency connector, and wherein a length by which the first test probe protrudes out of the housing or the medium is a first preset length; and
a second test probe arranged on the housing, wherein a test end of the second test probe and a test end of the first test probe are located at a same end of the housing, and wherein a length by which the second test probe protrudes out of the housing is a second preset length,
wherein the first preset length and the second preset length are both greater than a height of an avoidance device.

2. The probe structure of claim 1, wherein the first test probe is an elastic probe, and wherein the second test probe is a rigid probe.

3. The probe structure of claim 1, wherein the first test probe and the second test probe are arranged in parallel.

4. The probe structure of claim 3, wherein the first preset length is greater than the second preset length when the first test probe and the second test probe are both in a natural state.

5. The probe structure of claim 1, wherein a top end of the medium is flush with a top end of the housing, and wherein a bottom end of the medium is flush with a bottom end of the housing.

6. A radio frequency test apparatus, comprising:
a to-be-tested main board having a board surface, wherein a first patch and a second patch are arranged on the board surface;
a compensation board arranged in the to-be-tested main board, wherein the compensation board is arranged directly facing the first patch; and
a probe structure, comprising:
a housing;
a medium arranged in the housing;
a first test probe arranged in the medium and coaxial with the medium, wherein a signal end of the first test probe is configured to connect to a signal line of a radio frequency connector, wherein a test end of the first test probe is electrically connected to the first patch, and wherein a length by which the first test probe protrudes out of the housing or the medium is a first preset length; and
a second test probe arranged on the housing, wherein a test end of the second test probe is electrically connected to the second patch, wherein the test ends of the first and second test probes are located at a same end of the housing, and wherein a length by which the second test probe protrudes out of the housing is a second preset length,
wherein the first preset length and the second preset length are both greater than a height of an avoidance device, and
wherein the compensation board is electrically connected to the second test probe.

7. The radio frequency test apparatus of claim 6, wherein a grounding board is further arranged in the to-be-tested main board, wherein the second patch is electrically connected to the grounding board, and wherein the compensation board and the grounding board are integrally formed.

8. The radio frequency test of claim 6, wherein, when the probe structure is in a test state, the first test probe is in a compressed state and the first preset length is equal to the second preset length.

9. The radio frequency test apparatus of claim 6, wherein the compensation board is in a shape of a rectangle, a circle, or a regular polygon.

10. The radio frequency test apparatus of claim 9, wherein a size of the compensation board is related to the second preset length.

11. A radio frequency test system, comprising:
a to-be-tested main board;
a radio frequency connector;
a radio frequency cable;
a radio frequency tester; and
a probe structure for radio frequency testing that is electrically connected to the radio frequency tester by the radio frequency connector and the radio frequency cable, wherein a test end of the probe structure for radio frequency testing is electrically connected to the to-be-tested main board, the probe structure for radio frequency testing comprising:
a housing;
a medium arranged in the housing;
a first test probe arranged in the medium and coaxial with the medium, wherein a signal end of the first test probe is connected to a signal line of the radio frequency connector, and wherein a length by which the first test probe protrudes out of the housing or the medium is a first preset length; and
a second test probe arranged on the housing, wherein a test end of the first test probe and a test end of the second test probe are located at a same end of the housing, and wherein a length by which the second test probe protrudes out of the housing is a second preset length,
wherein the first preset length and the second preset length are both greater than a height of an avoidance device.

12. The radio frequency test system of claim 11, wherein the first test probe is an elastic probe, and wherein the second test probe is a rigid probe.

13. The radio frequency test system of claim 11, wherein the first test probe and the second test probe are arranged in parallel.

14. The radio frequency test system of claim 13, wherein the first preset length is greater than the second preset length when the first test probe and the second test probe are both in a natural state.

15. The radio frequency test system of claim 11, wherein a top end of the medium is flush with a top end of the housing, and wherein a bottom end of the medium is flush with a bottom end of the housing.

16. The probe structure of claim 4, wherein, when the probe structure is in a test state, the first test probe is in a compressed state and the first preset length is equal to the second preset length.

17. The radio frequency test apparatus of claim 6, wherein the second patch is electrically connected to the compensation board.

18. The radio frequency test apparatus of claim 6, wherein the first test probe is an elastic probe, and wherein the second test probe is a rigid probe.

19. The radio frequency test apparatus of claim 8, wherein the first preset length is greater than the second preset length when the first test probe and the second test probe are both in a natural state.

20. The radio frequency test system of claim 14, wherein, when the probe structure is in a test state, the first test probe is in a compressed state and the first preset length is equal to the second preset length.
